(19) United States
(12) Patent Application Publication
(10) Pub. No.: US 2025/0334951 A1
(43) Pub. Date: Oct. 30, 2025

(54) REFRIGERATION MANAGEMENT FOR INTERCONNECTED SYSTEMS

(71) Applicant: INTERNATIONAL BUSINESS MACHINES CORPORATION, ARMONK, NY (US)

(72) Inventors: Jing Lu, Beijing (CN); Dong Hui Liu, Beijing (CN); Peng Hui Jiang, Beijing (CN); Jun Su, Beijing (CN); Xiang Zu, BeiJing (CN); Jia Yu, BEIJING (CN)

(21) Appl. No.: 18/650,214

(22) Filed: Apr. 30, 2024

(51) Int. Cl. G05B 19/4155; H05K 7/20

(52) U.S. Cl. CPC G05B 19/4155; H05K 7/20827; H05K 7/20836; G05B 2219/49216

(57) ABSTRACT

An embodiment for managing refrigeration for interconnected systems is provided. The embodiment may include receiving historical data from one or more sources in a refrigeration area and one or more user-defined rules. The embodiment may also include identifying one or more units in the refrigeration area corresponding to a coverage of one or more cooling devices. The embodiment may further include creating a digital twin model of the refrigeration area including one or more cooling devices. The embodiment may also include identifying one or more refrigeration area parameters associated with the one or more units. The embodiment may further include in response to determining the refrigeration area requires management, executing a predicted action for at least one unit of the one or more units.

### BACKGROUND

The present invention relates generally to the field of computing, and more particularly to a system for managing refrigeration for interconnected systems.

Servers handle requests from client computers. These requests may be measured in requests per second (RPS). Multiple servers may operate together in a room. The temperature in the room may be impacted by the workload of the various servers. For example, the room temperature may increase when the servers are under a high workload. Conversely, the room temperature may decrease when the servers are under a low workload. In either case, the temperature in the room may be regulated to avoid a breakdown of the servers.

### SUMMARY

According to one embodiment, a method, computer system, and computer program product for managing refrigeration for interconnected systems is provided. The method, computer system, and computer program product may include receiving historical data from one or more sources in a refrigeration area and one or more user-defined rules. The method, computer system, and computer program product may also include identifying one or more units in the refrigeration area corresponding to a coverage of one or more cooling devices. The method, computer system, and computer program product may further include identifying one or more refrigeration area parameters associated with the one or more units based on the historical data. The method, computer system, and computer program product may also include in response to determining the refrigeration area requires management based on the one or more refrigeration area parameters and the one or more user-defined rules, executing a predicted action for at least one unit of the one or more units.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates an exemplary computing environment according to at least one embodiment.

FIG. 2 illustrates an operational flowchart for managing refrigeration for interconnected systems in a refrigeration management process according to at least one embodiment.

FIG. 3 is an exemplary diagram depicting a heatmap of environment temperature according to at least one embodiment.

FIG. 4 is an exemplary diagram depicting a heatmap of available power according to at least one embodiment.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

Embodiments of the present invention relate to the field of computing, and more particularly to a system for managing refrigeration for interconnected systems. The following described exemplary embodiments provide a system, method, and program product to, among other things, identify one or more refrigeration area parameters associated with one or more units based on historical data and, accordingly, execute a predicted action for at least one unit of the one or more units. Therefore, the present embodiment has the capacity to improve industrial technology by optimizing energy consumption.

As previously described, servers handle requests from client computers. These requests may be measured in requests per second (RPS). Multiple servers may operate together in a room. The temperature in the room may be impacted by the workload of the various servers. For example, the room temperature may increase when the servers are under a high workload. Conversely, the room temperature may decrease when the servers are under a low workload. In either case, the temperature in the room may be regulated to avoid a breakdown of the servers. The existing paradigm underutilizes the capabilities of refrigeration technology and has a limited ability to conserve energy. This problem is typically addressed by focusing on global temperature control. However, focusing on global temperature control neglects the potential for fine-grained air adjustment.

It may, therefore, be imperative to provide a method, computer system, and computer program product for leveraging refrigeration for precise temperature management.

According to at least one embodiment, a computer-based method, computer system, and computer program product for managing refrigeration for interconnected systems is provided. The computer-based method, computer system, and computer program product comprises receiving historical data from one or more sources in a refrigeration area and one or more user-defined rules, identifying one or more units in the refrigeration area corresponding to a coverage of one or more cooling devices, identifying one or more refrigeration area parameters associated with the one or more units based on the historical data, and in response to determining the refrigeration area requires management based on the one or more refrigeration area parameters and the one or more user-defined rules, executing a predicted action for at least one unit of the one or more units. This embodiment has the advantage of optimizing energy consumption.

According to at least one embodiment, executing the predicted action may further comprise creating a first polynomial regression model and a second polynomial regression model, where the first polynomial regression model predicts a target temperature of the one or more cooling devices based on the one or more refrigeration area parameters. The one or more refrigeration area parameters may be input into the second polynomial regression model together with the target temperature of the one or more cooling devices, where the second polynomial regression model may predict a wind velocity of the one or more cooling devices based on the one or more refrigeration area parameters and the target temperature. One or more settings of the at least one cooling device covering the at least one unit may be adjusted to match the predicted target temperature and the predicted wind velocity. This embodiment has the advantage of proactively adjusting refrigeration equipment for higher efficiency.

According to at least one embodiment, the one or more user-defined rules may include a probability value within a threshold of room temperature, a threshold for a lower proportion of available power, and a threshold for a higher proportion of available power. This embodiment has the advantage of enabling users to manually define rules to manage the refrigeration area.

According to at least one embodiment, determining whether the refrigeration area requires the management may further comprise identifying a room temperature value of the probability value for each unit according to the one or more user-defined rules, and in response to determining at least one identified room temperature value is greater than the threshold of room temperature, determining the at least one unit having the at least one identified room temperature value greater than the threshold of room temperature lacks cooling resources. This embodiment has the advantage of enhancing resource allocation.

According to at least one embodiment, determining whether the refrigeration area requires the management may further comprise identifying a power value of the probability value for each unit according to the one or more user-defined rules, and in response to determining a difference between a maximum power value and the identified power value for the at least one unit is lower than the threshold for the lower proportion of available power, determining the at least one unit having the difference lower than the threshold for the lower proportion of available power lacks the cooling resources. This embodiment has the advantage of adding resources to underserved areas.

According to at least one embodiment, in response to determining the difference between the maximum power value and the identified power value for the at least one unit is greater than the threshold for the higher proportion of available power, determining the at least one unit having the difference greater than the threshold for the higher proportion of available power may have an excessive amount of the cooling resources. This embodiment has the advantage of removing resources from overserved areas.

According to at least one embodiment, the one or more user-defined rules may further include a probability value of available power, where determining whether the refrigeration area requires the management may further comprise sorting the one or more units in a descending order according to the difference between the maximum power value and the identified power value for each unit, and identifying a first unit in the descending order as a recommended location for a new server. This embodiment has the advantage of optimizing the placement of new resources.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The following described exemplary embodiments provide a system, method, and program product to identify one or more refrigeration area parameters associated with one or more units based on historical data and, accordingly, execute a predicted action for at least one unit of the one or more units.

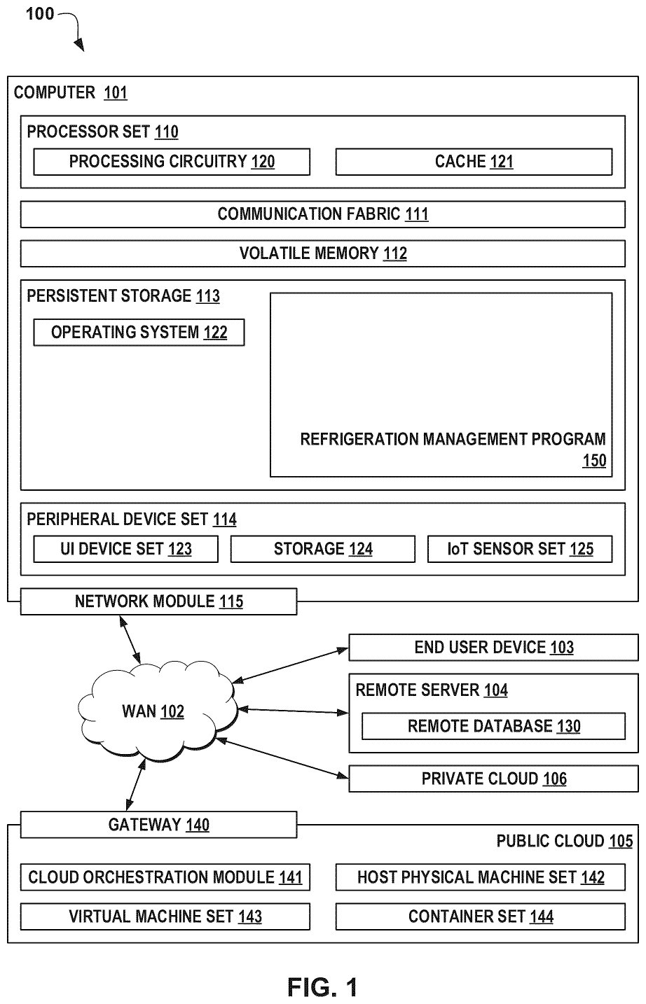

Referring to FIG. 1, an exemplary computing environment 100 is depicted, according to at least one embodiment. Computing environment 100 contains an example of an environment for the execution of at least some of the computer code involved in performing the inventive methods, such as a refrigeration management program 150. In addition to block 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 150, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 150 in persistent storage 113.

Communication fabric 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, the volatile memory 112 is characterized by random access, but this is not required unless affirmatively indicated. In computer 101, the volatile memory 112 is located in a single package and is internal to computer 101, but, alternatively or additionally, the volatile memory 112 may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage 113 allows writing of data, deletion of data and re-writing of data. Some familiar forms of persistent storage 113 include magnetic disks and solid state storage devices. Operating system 122 may take several forms, such as various known proprietary operating systems or open source Portable Operating System Interface type operating systems that employ a kernel. The code included in block 150 typically includes at least some of the computer code involved in performing the inventive methods.

Peripheral device set 114 includes the set of peripheral devices of computer 101. Data communication connections between the peripheral devices 114 and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database), this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector. Peripheral device set 114 may also include an air conditioner, a refrigerator, and/or any other cooling device.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN 102 and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments the private cloud 106 may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

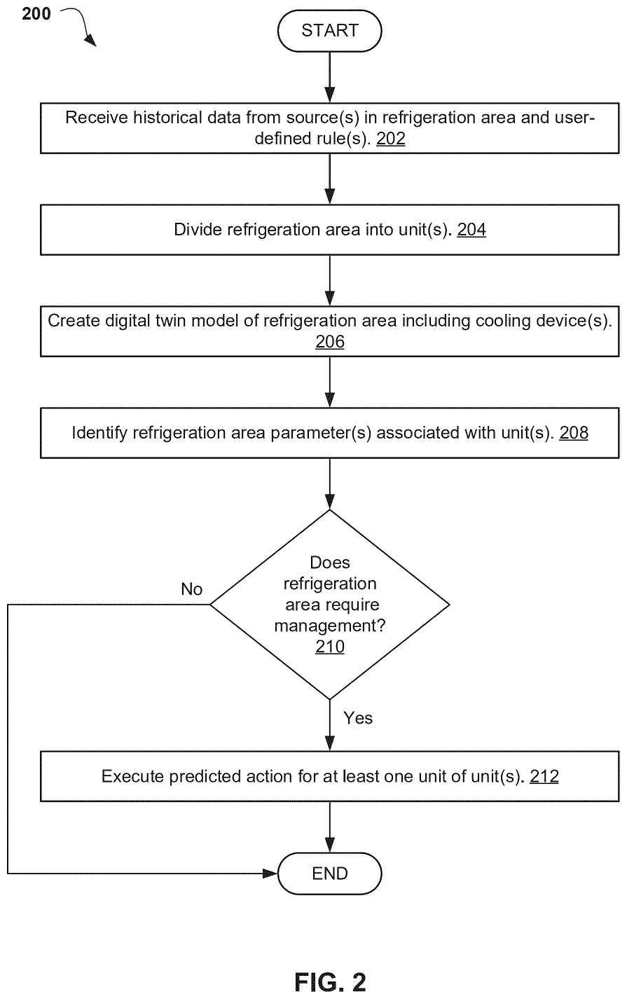

According to the present embodiment, the refrigeration management program 150 may be a program capable of receiving historical data from one or more sources in a refrigeration area, identifying one or more refrigeration area parameters associated with one or more units based on the historical data, and executing a predicted action for at least one unit of the one or more units. Furthermore, notwithstanding depiction in computer 101, the refrigeration management program 150 may be stored in and/or executed by, individually or in any combination, end user device 103, remote server 104, public cloud 105, and private cloud 106. The refrigeration management method is explained in further detail below with respect to FIG. 2. It may be appreciated that the examples described below are not intended to be limiting, and that in embodiments of the present invention the parameters used in the examples may be different.

Referring now to FIG. 2, an operational flowchart for managing refrigeration for interconnected systems in a refrigeration management process 200 is depicted according to at least one embodiment. At 202, the refrigeration management program 150 receives the historical data from the one or more sources in the refrigeration area and the one or more user-defined rules. As used herein, “refrigeration area” means a location where objects subject to overheating are stored. For example, the refrigeration area may be a location where server computers, such as remote server 104, are operating.

The historical data may include, but is not limited to, room temperature, power consumed by the one or more cooling devices, server workloads, refrigeration equipment action, server distance from each other, and/or cooling device distance from each other. The one or more sources may include external devices such a thermometer and/or a camera. For example, the thermometer may capture the room temperature and the camera may capture the server distance and the cooling device distance. Additionally, the one or more sources may include the servers and/or the cooling devices themselves. For example, the servers may report the workloads in requests per second (RPS) and the cooling devices may report the power consumption.

The one or more user-defined rules may include, but are not limited to, the probability value within the threshold of room temperature, the threshold for the lower proportion of available power, the threshold for the higher proportion of available power, and/or the probability value of available power.

For example, the probability value within the threshold of room temperature may include a probability value for room temperature and/or a probability value for consumed power. Specifically, the user may define the probability value for a specific temperature to occur as well as the probability value for a specific percentage of consumed power in relation to maximum power. The user may, for example, define the threshold of room temperature as 26° C. Thus, the rule may be that the room temperature should be less than 26° C. in 80% probability. Furthermore, the user may define, for example, an 80% probability value for consumed power. Continuing the example, the threshold for the lower proportion of available power may be 10% of maximum power, and the threshold for the higher proportion of available power may be 40% of maximum power. Finally, the user may define the probability value of available power. For example, the user may define the probability value of available power as 70%.

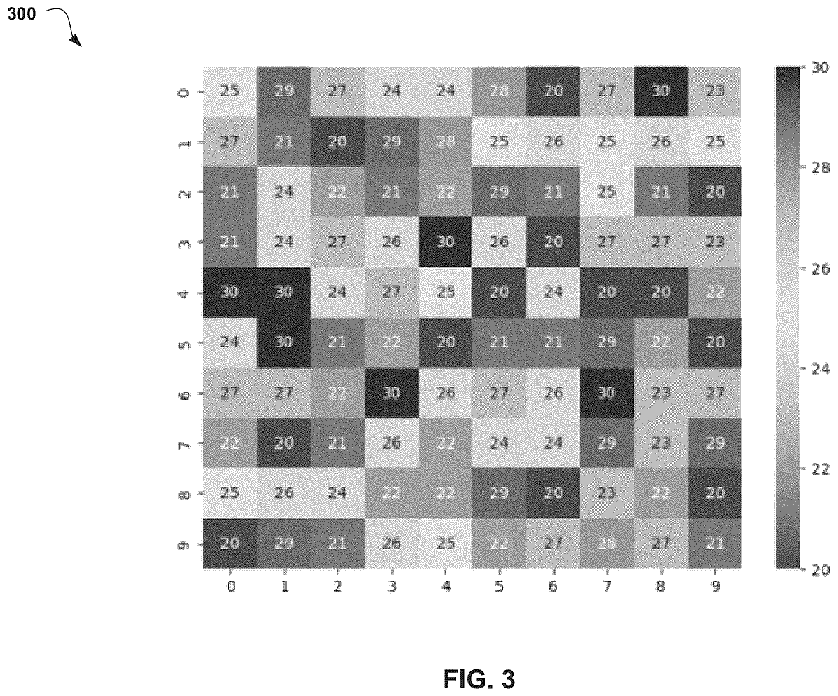

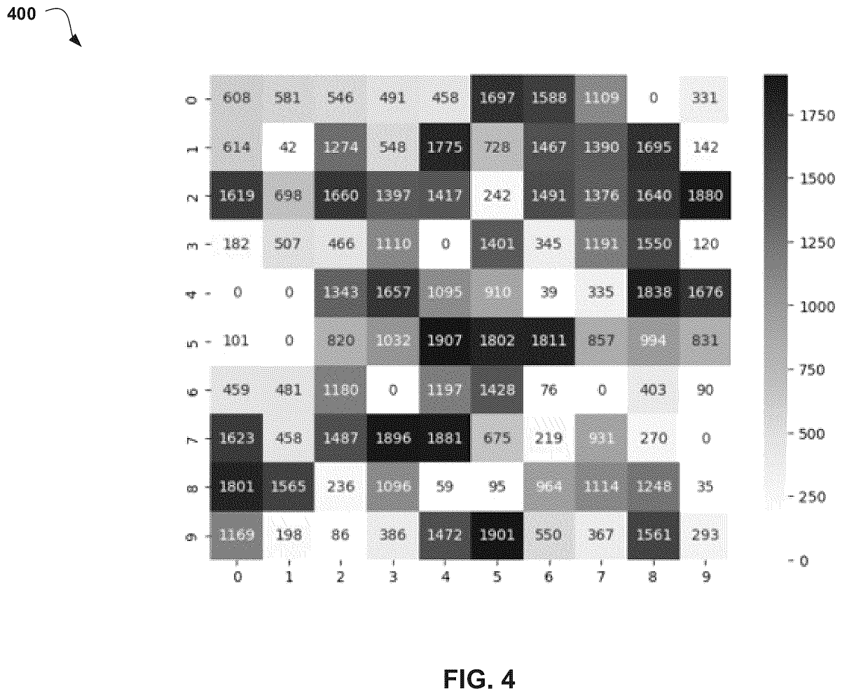

Then, at 204, the refrigeration management program 150 identifies one or more units in the refrigeration area corresponding to a coverage of one or more cooling devices. Examples of the cooling device may include, but are not limited to, an air conditioner, a refrigerator, and/or any other device used for cooling purposes. Since the refrigeration area may be too large for a single cooling device to handle, multiple cooling devices may be operating in the refrigeration area. The one or more cooling devices may be placed throughout the refrigeration area according to one or more zones. Based on the one or more zones, the refrigeration area may be divided into the one or more units. For example, the refrigeration area may be divided into 100 units, as illustrated in FIG. 3 and FIG. 4.

Next, at 206, the refrigeration management program 150 creates a digital twin model of the refrigeration area including the one or more cooling devices. The refrigeration management program 150 may use known techniques to create the digital twin model of the one or more cooling devices as well as the servers in the refrigeration area. The digital twin model of the refrigeration area may be leveraged to visualize the scene controlled (e.g., the refrigeration area). Additionally, the digital twin model of the refrigeration area may be useful in dividing the refrigeration area into the one or more units.

Then, at 208, the refrigeration management program 150 identifies the one or more refrigeration area parameters associated with the one or more units. The one or more refrigeration area parameters are identified based on the historical data. As described above with respect to step 202, the historical data may include, but is not limited to, room temperature, power consumed by the one or more cooling devices, server workloads, refrigeration equipment action, server distance from each other, and/or cooling device distance from each other. Therefore, the one or more refrigeration area parameters may also include room temperature, power consumed by the one or more cooling devices, server workloads, refrigeration equipment action, server distance from each other, and/or cooling device distance from each other. The one or more refrigeration area parameters may be identified on a unit-by-unit basis.

For example, the room temperature in a first unit may be 25° C., whereas the room temperature in a second unit may be 28° C. The power consumed by a first cooling device in the first unit may be 95% of maximum power in terms of kilowatts (kw), whereas the power consumed by a second cooling device in the second unit may be 20% of maximum power in terms of kw. The server workloads in the first unit may be 50 RPS, whereas the server workloads in the second unit may be 75 RPS. The refrigeration equipment action in the first unit may be to increase the refrigeration temperature, whereas the refrigeration equipment action in the second unit may be to decrease the refrigeration temperature. Server A and Server B may be 3 meters (m) apart in the first unit, whereas Server C and Server D may be 5 m apart in the second unit. Similarly, Cooling Device A and Cooling Device B may be 3 m apart in the first unit, whereas Cooling Device C and Cooling Device D may be 5 m apart in the second unit. It may be appreciated that the parameters set forth in the examples above are identified at specific instances in time, and that in embodiments of the invention the parameters may vary across a time range. For example, the room temperature in the first unit may vary between 20° C. and 25° C. across a given time range.

Next, at 210, the refrigeration management program 150 determines whether the refrigeration area requires the management. The determination is made based on the one or more refrigeration area parameters and the one or more user-defined rules.

According to at least one embodiment, when the refrigeration area requires the management, the settings of at least one of the one or more cooling devices may be adjusted. A time series model for workload running on each server may be created to capture the workload change pattern. The time series model may then be used to predict the future workloads based on the past workloads in the historical data. Once the future workloads have been predicted, multiple polynomial regression models may be created to inference the relationships between the one or more refrigeration area parameters. The multiple polynomial regression models may include a first polynomial regression model and a second polynomial regression model. The one or more refrigeration area parameters may be inputted into the first polynomial regression model, and the first polynomial regression model may output a prediction for a target temperature of the one or more cooling devices based on the one or more refrigeration area parameters. For example, the one or more refrigeration area parameters inputted into the first polynomial regression model may include the predicted server workloads, server distance, cooling device distance, and a target room temperature.

The one or more refrigeration area parameters may be inputted into the second polynomial regression model together with the target temperature of the one or more cooling devices. The second polynomial regression model may output a prediction for the wind velocity of the one or more cooling devices based on the one or more refrigeration area parameters and the target temperature. The formula for the multiple polynomial regression models may be as follows: Y=a0+a1*X1+a2*X2+a3*X3 . . . +ak*Xm, where Y=room temperature, X1=wind velocity, X2=cooling device target temperature, X3=server distance, Xm=RPS of server workloads (e.g., workload 1, workload 2 . . . workload m), and a=a coefficient learned by a machine learning model during training.

According to at least one other embodiment, the refrigeration area may require the management when the refrigeration area lacks the cooling resources or has an excessive amount of the cooling resources. The room temperature value of the probability value may be identified for each unit according to the one or more user-defined rules. A kernel density estimation (KDE) algorithm may be used by the refrigeration management program 150 to inference the probability distribution of room temperature and power consumption. For example, where the threshold of room temperature is 26° C. and the probability value is the room temperature value in 80% probability, the KDE algorithm may inference the room temperature of each unit in 80% probability. For example, the room temperature at 80% probability in the first unit may be 25° C., whereas the room temperature at 80% probability in the second unit may be 29° C. In response to determining the at least one identified room temperature value is greater than the threshold of room temperature, it may be determined that the at least one unit having the at last one identified room temperature value greater than the threshold of room temperature lacks the cooling resources. Continuing the example described above, the second unit may lack the cooling resources.

Additionally, the power value of the probability value may be identified for each unit according to the one or more user-defined rules. The KDE algorithm may be used by the refrigeration management program 150 to inference the probability distribution of power consumption. For example, where the probability value is the consumed power value in 80% probability, the KDE algorithm may inference the power value of each unit in 80% probability. For example, the power value at 80% probability in the first unit may be 95% of maximum power in terms of kw, whereas the power value at 80% probability in the second unit may be 20% of maximum power in terms of kw. In response to determining the difference between the maximum power value and the identified power value for the at least one unit is lower than the threshold for the lower proportion of available power, it may be determined the at last one unit having the difference lower than the threshold for the lower proportion of available power lacks the cooling resources. Continuing the example described above, assuming the threshold for the lower proportion of available power is 10% of maximum power, for the first unit 100%-95%=5% is lower than the threshold for the lower proportion of available power. Thus, in this example, the first unit may be the at least one unit that lacks the cooling resources. In response to determining the difference between the maximum power value and the identified power value for the at least one unit is greater than the threshold for the higher proportion of available power, it may be determined the at least one unit having the difference greater than the threshold for the higher proportion of available power has the excessive amount of the cooling resources. Continuing the example described above, assuming the threshold for the higher proportion of available power is 40% of maximum power, for the second unit 100%-20%=80% is greater than the threshold for the higher proportion of available power. Thus, in this example, the second unit may be the at least one unit that has the excessive amount of the cooling resources.

According to at least one further embodiment, the refrigeration area may require the management when a new server is to be placed in the refrigeration area. The user may define the probability value of available power. For example, the user may define the probability value of available power as 70%. As described above, the KDE algorithm may inference the room temperature of each unit according to the probability value. In this instance, the probability value may be 70%. For example, the room temperature at 70% probability in the first unit may be 20° C., whereas the room temperature at 70% probability in the second unit may be 32° C. When the room temperature is higher than the threshold of room temperature, it may be determined that the at least one unit is not a proper unit for the new server. For example, when the threshold of room temperature is 26° C., the 32° C. value of the second unit exceeds the threshold of room temperature. Thus, in this example, the second unit may not be proper for the new server. Then, KDE algorithm may be used by the refrigeration management program 150 to inference the probability distribution of power consumption. For example, where the probability value is the consumed power value in 70% probability, the KDE algorithm may inference the power value of each unit in 70% probability. For example, the power value at 70% probability in the first unit may be 97% of maximum power in terms of kw, whereas the power value at 70% probability in the second unit may be 30% of maximum power in terms of kw. Then, the difference between maximum power and the power value may be determined. Continuing the example described above, for the first unit 100%-97%=3% and for the second unit 100%-30%=70%. The one or more units may be sorted in a descending order according to the difference between the maximum power value and the identified power value for each unit. Continuing the example, the second unit having 70% available power may be placed first in the descending order, followed by the first unit having 3% available power. The first unit in the descending order may be identified as a recommended location for the new server. Continuing the example, the second unit having 70% available power may be the first unit in the descending order.

In response to determining the refrigeration area requires the management (step 210, “Yes” branch), the refrigeration management process 200 proceeds to step 212 to execute the predicted action for the at least one unit of the one or more units. In response to determining the refrigeration area does not require the management (step 210, “No” branch), the refrigeration management process 200 ends.

Then, at 212, the refrigeration management program 150 executes the predicted action for the at least one unit of the one or more units. According to at least one embodiment, where the value of room temperature is greater than the threshold of room temperature in the at least one unit, the executed predicted action may include adjusting the one or more settings (e.g., wind velocity of the cooling device and/or temperature of the cooling device) of the at least one cooling device covering the at least one unit to match the predicted target temperature and the predicted wind velocity. For example, where the predicted target temperature is 20° C., the temperature of the at least one cooling device may be adjusted to 20° C.

According to at least one other embodiment, where the refrigeration area lacks the cooling resources or has the excessive amount of the cooling resources, the executed predicted action may include rearranging the one or more cooling devices. For example, for the at least one unit having the excessive amount of the cooling resources, one or more cooling devices in those units may be moved to the at least one unit lacking the cooling resources. The one or more cooling devices may be moved by sending a signal to the one or more cooling devices to move to the appropriate units assuming the one or more cooling devices are mobile. If the one or more cooling devices are not self-mobile, then a robotic device may be deployed to move those cooling devices that are not self-mobile.

According to at least one further embodiment, where new server is to be placed in the refrigeration area, the executed predicted action may include placing the new server in the recommended location. For example, where the second unit is atop the descending order list, the new server may be placed within the second unit. Continuing the example, the robotic device may be deployed to move the new server into the second unit.

Referring now to FIG. 3, an exemplary diagram 300 depicting a heatmap of environment temperature is shown according to at least one embodiment. In the diagram 300, the heatmap of environment temperature depicts the room temperature in Celsius of a refrigeration area divided into 100 units. The heatmap depicts the room temperature according to the probability value selected by the user. For example, the probability value selected by the user may be the room temperature in 80% probability. Continuing the example, the room temperature in 80% probability may be as follows: 25° C. in unit 0-0, 29° C. in unit 0-1, 27° C. in unit 0-2, 24° C. in unit 0-3, 24° C. in unit 0-4, 28° C. in unit 0-5, 20° C. in unit 0-6, 27° C. in unit 0-7, 30° C. in unit 0-8, 23° C. in unit 0-9, and so on. The heatmap of environment temperature may be utilized to determine those unites requiring the management.

Referring now to FIG. 4, an exemplary diagram 400 depicting a heatmap of available power is shown according to at least one embodiment. In the diagram 400, the heatmap of available power depicts the available power in kw of a refrigeration area divided into 100 units. The heatmap depicts the available power according to the probability value selected by the user. For example, the probability value selected by the user may be the available power in 80% probability. Continuing the example, the available power in 80% probability may be as follows: 608 kw in unit 0-0, 581 kw in unit 0-1, 546 kw in unit 0-2, 491 kw in unit 0-3, 458 kw in unit 0-4, 1697 kw in unit 0-5, 1588 kw in unit 0-6, 1109 kw in unit 0-7, 0 kw in unit 0-8, 331 kw in unit 0-9, and so on. The heatmap of available power may also be utilized to determine those unites requiring the management.

It may be appreciated that FIGS. 2, 3, and 4 provide only an illustration of one implementation and do not imply any limitations with regard to how different embodiments may be implemented. Many modifications to the depicted environments may be made based on design and implementation requirements.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computer-based method of managing refrigeration for interconnected systems, the method comprising:
receiving historical data from one or more sources in a refrigeration area and one or more user-defined rules;
identifying one or more units in the refrigeration area corresponding to a coverage of one or more cooling devices;
identifying one or more refrigeration area parameters associated with the one or more units based on the historical data;
determining whether the refrigeration area requires management based on the one or more refrigeration area parameters and the one or more user-defined rules; and
in response to determining the refrigeration area requires the management, executing a predicted action for at least one unit of the one or more units.

2. The computer-based method of claim 1, wherein executing the predicted action further comprises:
creating a first polynomial regression model and a second polynomial regression model;
inputting the one or more refrigeration area parameters into the first polynomial regression model, wherein the first polynomial regression model predicts a target temperature of the one or more cooling devices based on the one or more refrigeration area parameters;
inputting the one or more refrigeration area parameters into the second polynomial regression model together with the target temperature of the one or more cooling devices, wherein the second polynomial regression model predicts a wind velocity of the one or more cooling devices based on the one or more refrigeration area parameters and the target temperature; and
adjusting one or more settings of at least one cooling device covering the at least one unit to match the predicted target temperature and the predicted wind velocity.

3. The computer-based method of claim 1, wherein the one or more user-defined rules include a probability value within a threshold of room temperature, a threshold for a lower proportion of available power, and a threshold for a higher proportion of available power.

4. The computer-based method of claim 3, wherein determining whether the refrigeration area requires the management further comprises:
identifying a room temperature value of the probability value for each unit according to the one or more user-defined rules; and
in response to determining at least one identified room temperature value is greater than the threshold of room temperature, determining the at least one unit having the at least one identified room temperature value greater than the threshold of room temperature lacks cooling resources.

5. The computer-based method of claim 4, wherein determining whether the refrigeration area requires the management further comprises:
identifying a power value of the probability value for each unit according to the one or more user-defined rules; and
in response to determining a difference between a maximum power value and the identified power value for the at least one unit is lower than the threshold for the lower proportion of available power, determining the at least one unit having the difference lower than the threshold for the lower proportion of available power lacks the cooling resources.

6. The computer-based method of claim 5, wherein in response to determining the difference between the maximum power value and the identified power value for the at least one unit is greater than the threshold for the higher proportion of available power, determining the at least one unit having the difference greater than the threshold for the higher proportion of available power has an excessive amount of the cooling resources.

7. The computer-based method of claim 6, wherein the one or more user-defined rules further include a probability value of available power, wherein determining whether the refrigeration area requires the management further comprises:
sorting the one or more units in a descending order according to the difference between the maximum power value and the identified power value for each unit; and
identifying a first unit in the descending order as a recommended location for a new server.

8. A computer system, the computer system comprising:
one or more processors, one or more computer-readable memories, one or more computer-readable tangible storage medium, and program instructions stored on at least one of the one or more computer-readable tangible storage medium for execution by at least one of the one or more processors via at least one of the one or more computer-readable memories, wherein the computer system is capable of performing a method comprising:
receiving historical data from one or more sources in a refrigeration area and one or more user-defined rules;
identifying one or more units in the refrigeration area corresponding to a coverage of one or more cooling devices;
identifying one or more refrigeration area parameters associated with the one or more units based on the historical data;
determining whether the refrigeration area requires management based on the one or more refrigeration area parameters and the one or more user-defined rules; and
in response to determining the refrigeration area requires the management, executing a predicted action for at least one unit of the one or more units.

9. The computer system of claim 8, wherein executing the predicted action further comprises:
creating a first polynomial regression model and a second polynomial regression model;
inputting the one or more refrigeration area parameters into the first polynomial regression model, wherein the first polynomial regression model predicts a target temperature of the one or more cooling devices based on the one or more refrigeration area parameters;
inputting the one or more refrigeration area parameters into the second polynomial regression model together with the target temperature of the one or more cooling devices, wherein the second polynomial regression model predicts a wind velocity of the one or more cooling devices based on the one or more refrigeration area parameters and the target temperature; and
adjusting one or more settings of at least one cooling device covering the at least one unit to match the predicted target temperature and the predicted wind velocity.

10. The computer system of claim 8, wherein the one or more user-defined rules include a probability value within a threshold of room temperature, a threshold for a lower proportion of available power, and a threshold for a higher proportion of available power.

11. The computer system of claim 10, wherein determining whether the refrigeration area requires the management further comprises:
identifying a room temperature value of the probability value for each unit according to the one or more user-defined rules; and
in response to determining at least one identified room temperature value is greater than the threshold of room temperature, determining the at least one unit having the at least one identified room temperature value greater than the threshold of room temperature lacks cooling resources.

12. The computer system of claim 11, wherein determining whether the refrigeration area requires the management further comprises:
identifying a power value of the probability value for each unit according to the one or more user-defined rules; and
in response to determining a difference between a maximum power value and the identified power value for the at least one unit is lower than the threshold for the lower proportion of available power, determining the at least one unit having the difference lower than the threshold for the lower proportion of available power lacks the cooling resources.

13. The computer system of claim 12, wherein in response to determining the difference between the maximum power value and the identified power value for the at least one unit is greater than the threshold for the higher proportion of available power, determining the at least one unit having the difference greater than the threshold for the higher proportion of available power has an excessive amount of the cooling resources.

14. The computer system of claim 13, wherein the one or more user-defined rules further include a probability value of available power, wherein determining whether the refrigeration area requires the management further comprises:
sorting the one or more units in a descending order according to the difference between the maximum power value and the identified power value for each unit; and
identifying a first unit in the descending order as a recommended location for a new server.

15. A computer program product, the computer program product comprising:
one or more computer-readable tangible storage medium and program instructions stored on at least one of the one or more computer-readable tangible storage medium, the program instructions executable by a processor capable of performing a method, the method comprising:
receiving historical data from one or more sources in a refrigeration area and one or more user-defined rules;
identifying one or more units in the refrigeration area corresponding to a coverage of one or more cooling devices;
identifying one or more refrigeration area parameters associated with the one or more units based on the historical data;
determining whether the refrigeration area requires management based on the one or more refrigeration area parameters and the one or more user-defined rules; and
in response to determining the refrigeration area requires the management, executing a predicted action for at least one unit of the one or more units.

16. The computer program product of claim 15, wherein executing the predicted action further comprises:
creating a first polynomial regression model and a second polynomial regression model;
inputting the one or more refrigeration area parameters into the first polynomial regression model, wherein the first polynomial regression model predicts a target temperature of the one or more cooling devices based on the one or more refrigeration area parameters;
inputting the one or more refrigeration area parameters into the second polynomial regression model together with the target temperature of the one or more cooling devices, wherein the second polynomial regression model predicts a wind velocity of the one or more cooling devices based on the one or more refrigeration area parameters and the target temperature; and
adjusting one or more settings of at least one cooling device covering the at least one unit to match the predicted target temperature and the predicted wind velocity.

17. The computer program product of claim 15, wherein the one or more user-defined rules include a probability value within a threshold of room temperature, a threshold for a lower proportion of available power, and a threshold for a higher proportion of available power.

18. The computer program product of claim 17, wherein determining whether the refrigeration area requires the management further comprises:
identifying a room temperature value of the probability value for each unit according to the one or more user-defined rules; and
in response to determining at least one identified room temperature value is greater than the threshold of room temperature, determining the at least one unit having the at least one identified room temperature value greater than the threshold of room temperature lacks cooling resources.

19. The computer program product of claim 18, wherein determining whether the refrigeration area requires the management further comprises:
identifying a power value of the probability value for each unit according to the one or more user-defined rules; and
in response to determining a difference between a maximum power value and the identified power value for the at least one unit is lower than the threshold for the lower proportion of available power, determining the at least one unit having the difference lower than the threshold for the lower proportion of available power lacks the cooling resources.

20. The computer program product of claim 19, wherein in response to determining the difference between the maximum power value and the identified power value for the at least one unit is greater than the threshold for the higher proportion of available power, determining the at least one unit having the difference greater than the threshold for the higher proportion of available power has an excessive amount of the cooling resources.
